(19) United States
(12) Patent Application Publication
(10) Pub. No.: US 2024/0178162 A1
(43) Pub. Date: May 30, 2024

(54) INTEGRATED CIRCUIT PACKAGES INCLUDING A GLASS CORE WITH A FILTER STRUCTURE

(71) Applicant: Intel Corporation, Santa Clara, CA (US)

(72) Inventors: Jeremy Ecton, Gilbert, AZ (US); Aleksandar Aleksov, Chandler, AZ (US); Brandon C. Marin, Gilbert, AZ (US); Srinivas V. Pietambaram, Chandler, AZ (US); Hiroki Tanaka, Gilbert, AZ (US)

(73) Assignee: Intel Corporation, Santa Clara, CA (US)

(21) Appl. No.: 18/060,125

(22) Filed: Nov. 30, 2022

(51) Int. Cl. H01L 23/66; H01L 23/13; H01L 23/15; H01L 23/498

(52) U.S. Cl. CPC H01L 23/66; H01L 23/13; H01L 23/15; H01L 23/49822; H01L 23/49838; H01L 23/49894; H01L 2223/6616

(57) ABSTRACT

An integrated circuit (IC) package substrate including a glass core having a cavity filter structure, and related devices and methods, are disclosed herein. In some embodiments, an IC package substrate may include a core made of glass, and the core including a first core portion having a first surface and a trench and a ridge in the first surface, the trench and the ridge lined with a conductive material; and a second core portion having a second surface, the second surface lined with the conductive material, wherein the first surface of the first core portion is physically coupled to the second surface of the second core portion forming a cavity filter structure.

### TECHNICAL FIELD

The present disclosure relates to integrated circuit (IC) packages. More specifically, it relates to techniques, methods, and apparatus directed to a substrate with a glass core and an integrated cavity filter architectures.

### BACKGROUND

With a surge in demand for high-speed communication services, low latency solutions with high data rates and bandwidth density have emerged. To meet the requirements of higher bandwidth density at millimeter wave or RF frequencies, multiplexed solutions are required.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1C are schematic cross-sectional views of example glass cores with filter structures according to some embodiments of the present disclosure.

FIG. 1D is a schematic top view of the example glass cores of FIGS. 1A-1C along line A-A′.

FIGS. 2A and 2B are schematic cross-sectional views of other example glass cores with filter structures according to some embodiments of the present disclosure.

FIGS. 3A-3F are schematic cross-sectional views of different stages of an example process for manufacturing the glass core with the filter structure of FIG. 1B according to some embodiments of the present disclosure.

FIGS. 4A-4C are schematic cross-sectional views of different stages of an example process for manufacturing an example glass core with a filter structure according to some embodiments of the present disclosure.

FIG. 5 is a cross-sectional view of an example microelectronic assembly according to some embodiments of the present disclosure.

FIG. 6 is a block diagram of an example computing device in accordance with any of the embodiments disclosed herein.

### DETAILED DESCRIPTION

The demand for miniaturization of form factor and increased levels of integration for high performance are driving sophisticated packaging approaches in the semiconductor industry. Die partitioning enables miniaturization of small form factor and high performance without yield issues seen with other methods but needs fine die to die interconnections. Embedded Multi-die Interconnect Bridge (EMIB) enables a lower cost and simpler 2.5D packaging approach for very high-density interconnects between heterogeneous dies on a single package. Instead of an expensive silicon interposer with through-silicon vias (TSVs), a small silicon bridge chip is embedded in the package, enabling very high density die-to-die connections only where needed. Standard flip-chip assembly may be used for robust power delivery and to connect high-speed signals directly from chip to the package substrate. For future generations of die partitioning, several bridges that connect the dies at finer bump pitches (e.g., 25 microns and smaller) are needed. Another option for enabling fine die-to-die interconnections is incorporating a thin glass core into the substrate package. Glass core compared to conventional epoxy core offers several advantages including a higher plated through-hole (PTH) density, lower signal losses, and lower total thickness variation (TTV), among others. Solutions which increase the functionality of the glass core are desired, such as, passives embedded in the glass core (e.g., cavity filters, amplifiers, and similar passives). In particular, for 5G and millimeter wave applications incorporating cavity filters in substrate package is of increasing interest. Accordingly, embodiments disclosed herein include integrating cavity filters within a glass core of a package substrate, as well as in other elements of an electronic device where glass is the medium (e.g., a glass interposer, a glass patch, etc.).

Cavity filter architectures may be integrated into a glass core of a package substrate using a laser-assisted etching process. In a particular embodiment, the RF filter components are fabricated in the glass core. The laser-assisted etching process allows for smaller dimensions, closer spacings, and improved alignment. Generally, laser-assisted etching processes involve exposing the core to a laser. The laser exposure results in a change in the morphology of the exposed regions. For example, in a glass core, the structure may turn from amorphous to crystalline after exposure by the laser. The change in structure allows for selective etching of the exposed regions. After etching, conductive material may be disposed in the openings. The laser-assisted etching process allows for the formation of crack free, high-density trenches and ridges into the glass core.

Accordingly, microelectronic assemblies including glass cores having cavity filter structures, and related devices and methods, are disclosed herein. In some embodiments, a package substrate may include a core made of glass, and the core including a first core portion having a first surface and a trench and a ridge in the first surface, the trench and the ridge lined with a conductive material; and a second core portion having a second surface, the second surface lined with the conductive material, wherein the first surface of the first core portion is physically coupled to the second surface of the second core portion forming a cavity filter structure.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “chiplet,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. A dielectric material may include any suitable dielectric material commonly used in semiconductor manufacture, such as silicon and one or more of oxygen, nitrogen, hydrogen, and carbon (e.g., in the form of silicon oxide, silicon nitride, silicon oxynitride, or silicon carbon nitride); a polyimide material; or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides, including optical fiber, optical splitters, optical combiners, optical couplers, and optical vias.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes a core with dielectric material having conductive pathways (e.g., interconnect layers or redistribution layers) on top and/or bottom surfaces of the core. A core may include a material, such as glass, that provides mechanical stability and support to the package substrate. A package substrate may further refer to a substrate that includes layers of build-up film.

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in some embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example,” an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

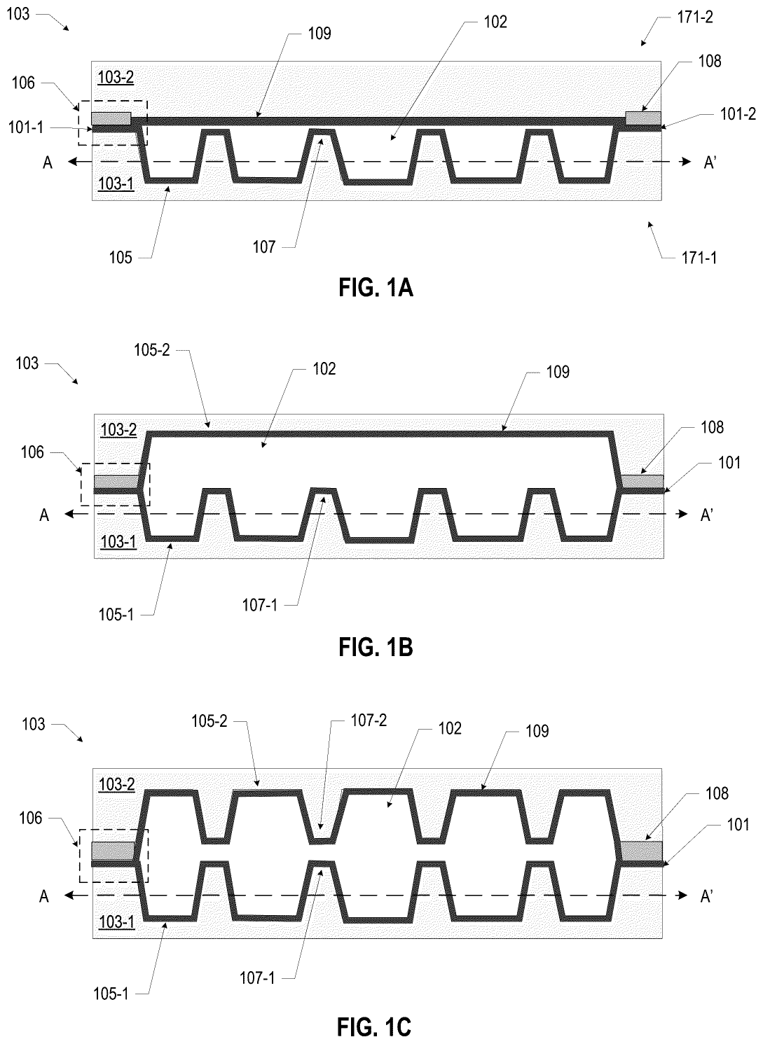

For convenience, if a collection of drawings designated with different letters are present (e.g., FIGS. 1A-1D), such a collection may be referred to herein without the letters (e.g., as “FIG. 1”). Similarly, if a collection of reference numerals designated with different numerals are present (e.g., 109-1, 109-2), such a collection may be referred to herein without the numerals or letters (e.g., as “109”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

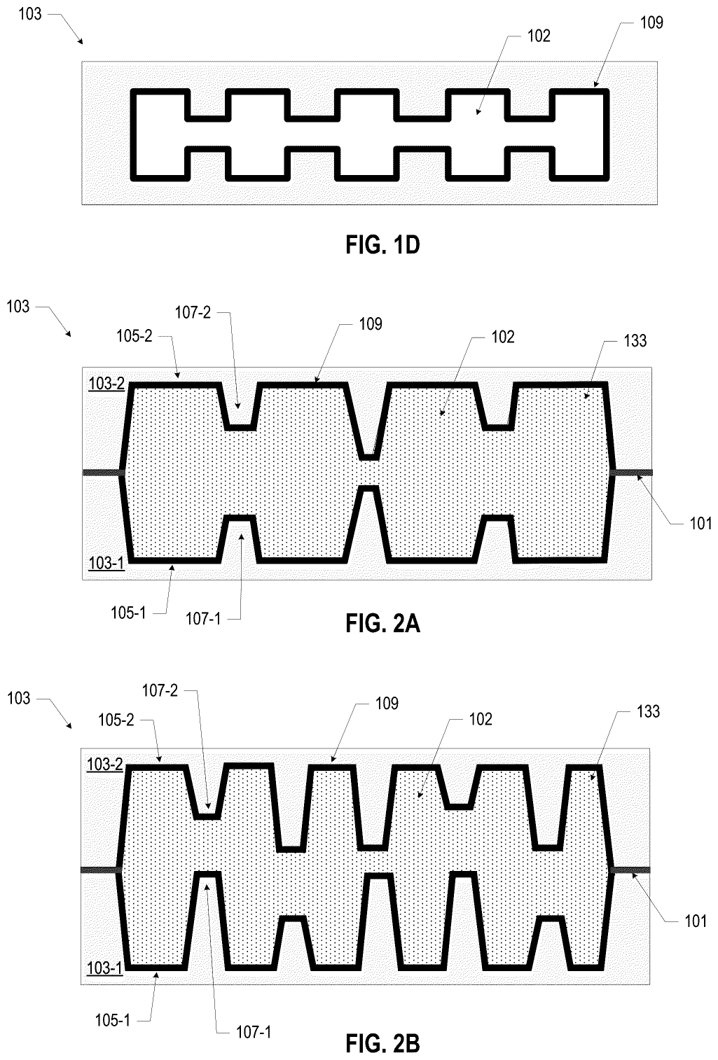

FIG. 1A is a schematic cross-sectional view of an example core with a filter structure according to some embodiments of the present disclosure. Core 103 may include a cavity filter structure 102. The cavity filter structure 102 may be formed by bonding a first core portion 103-1, having trenches 105 and ridges 107 lined by a conductive material 109, to a second core portion 103-2, having a surface lined by a conductive material 109. The conductive material 109 may include any suitable conductive material, such as a metal (e.g., copper). The first core portion 103-1 may be bonded to the second core portion 103-2 at a bonding interface 106. The bonding interface 106 may extend along a perimeter of the first and second core portions 103-1, 103-2 (e.g., at sidewalls along a perimeter of the first and second core portions 103-1, 103-2). The first core portion 103-1 may be physically coupled to the second core portion 103-2 using any suitable attachment means, for example, the bonding interface 106 may include a bonding material 108, such as, a die attach film (DAF), a non-conductive adhesive, a B-stage underfill, or a polymer film with adhesive property. The core 103 (e.g., the first and second core portions 103-1, 103-2) may include glass. For example, a core 103 may include any suitable type of glass known in the art, including but not limited to photoglass, borosilicate glass, soda lime glass, quartz, fused silica, ceramic glass, or other glass material. In some embodiments, the core 103 may include a photoimageable glass, or other borosilicate-based glasses with oxide additions. In some embodiments, the core 103 may further include a ceramic material, silicon, or other non-conductive semiconductor materials. In some embodiments, the bonding interface 106 may not include a bonding material 108 and, instead, the first core portion 103-1 may be coupled to the second core portion 103-2 by glass-to-glass bonding (e.g., as shown in FIG. 2). The core 103 may further include a signal trace inlet and outlet 101. A signal may enter the cavity filter structure 102 through the signal trace inlet 101-1. As the signal transmits through the core 103, the cavity filter structure 102 may filter the signal to a particular frequency or frequency band and output the filtered signal through the outlet 101-2. Although FIG. 1A illustrates the signal trace inlet 101-1 on the left and the signal trace outlet 101-2 on the right, the signal trace inlet and outlets 101 may be in either position. A thickness (e.g., between a first surface 171-1 and a second surface 171-2) of a core 103 may be between 20 microns and 2 millimeters.

FIG. 1B is a schematic cross-sectional view of another example core with a filter structure according to some embodiments of the present disclosure. The configuration of the embodiment shown in the figure is like that of FIG. 1A, except for differences as described further. The configuration of the core 103 having a cavity filter structure 102 described herein includes a second core portion 103-2 having a trench 105 lined by a conductive material 109, where the cavity filter structure 102 may be formed by bonding a first core portion 103-1, having first trenches 105-1 and first ridges 107-1 lined by a conductive material 109, to a second core portion 103-2, having a second trench 105-2 lined by a conductive material 109.

FIG. 1C is a schematic cross-sectional view of another example core with a filter structure according to some embodiments of the present disclosure. The configuration of the embodiment shown in the figure is like that of FIG. 1A, except for differences as described further. The configuration of the core 103 having a cavity filter structure 102 described herein includes a second core portion 103-2 having second trenches 105-2 and second ridges 107-2 lined by a conductive material 109, where the cavity filter structure 102 may be formed by bonding a first core portion 103-1, having first trenches 105-1 and first ridges 107-1 lined by a conductive material 109, to a second core portion 103-2, having second trenches 105-2 and second ridges 107-2 lined by a conductive material 109, where the first and second trenches 105-1, 105-2 and the first and second ridges 107-1, 107-2 are symmetrical and aligned.

FIG. 1D is a schematic top view of the example cores of FIGS. 1A-1C along line A-A′. The core 103 may include the cavity filter structure 102 lined by the conductive material 109.

FIG. 2A is a schematic cross-sectional view of another example core with a filter structure according to some embodiments of the present disclosure. The configuration of the embodiment shown in the figure is like that of FIG. 1C, except for differences as described further. The configuration of the core 103 having a cavity filter structure 102, where the cavity filter structure 102 may be formed by bonding a first core portion 103-1, having first trenches 105-1 and first ridges 107-1 lined by a conductive material 109, to a second core portion 103-2, having second trenches 105-2 and second ridges 107-2 lined by a conductive material 109, where the first and second trenches 105-1, 105-2 and the first and second ridges 107-1, 107-2 are symmetrical and aligned. The core 103 may further include an insulating material 133 in the cavity filter structure 102. An insulating material 133 may include a mold material, such as an organic polymer with inorganic silica particles, or an epoxy material. In some embodiments, the insulating material 133 is a dielectric material. In some embodiments, the dielectric material may include an organic dielectric material, a fire retardant grade 4 material (FR-4), BT resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics). In some embodiments, the insulating material 133 includes a photoresist material, a sacrificial material, or a thermal decomposable material. The insulating material 133 may be formed using any suitable process, including lamination, or slit coating and curing. In some embodiments, the insulating material 133 may be dispensed in liquid form, and, subsequently, may be subjected to a process, for example, curing, that solidifies the insulating material 133. In some embodiments, the insulating material 133 may be omitted (e.g., as shown in FIG. 1).

FIG. 2B is a schematic cross-sectional view of another example core with a filter structure according to some embodiments of the present disclosure. The configuration of the embodiment shown in the figure is like that of FIG. 2A, except for differences as described further. The configuration of the core 103 having a cavity filter structure 102, where the cavity filter structure 102 may be formed by bonding a first core portion 103-1, having first trenches 105-1 and first ridges 107-1 lined by a conductive material 109, to a second core portion 103-2, having second trenches 105-2 and second ridges 107-2 lined by a conductive material 109, where the first and second trenches 105-1, 105-2 and the first and second ridges 107-1, 107-2 are asymmetrical and may not be aligned.

Although FIGS. 1 and 2 illustrate a particular number and arrangement of trenches and ridges with a particular geometry (e.g., trenches and ridges with sloped sidewalls), a core 103 with a filter structure 102 may includes any suitable number and arrangement of trenches and ridges with any suitable geometries (e.g., straight sidewalls) to filter a signal to a particular desired frequency or frequency band.

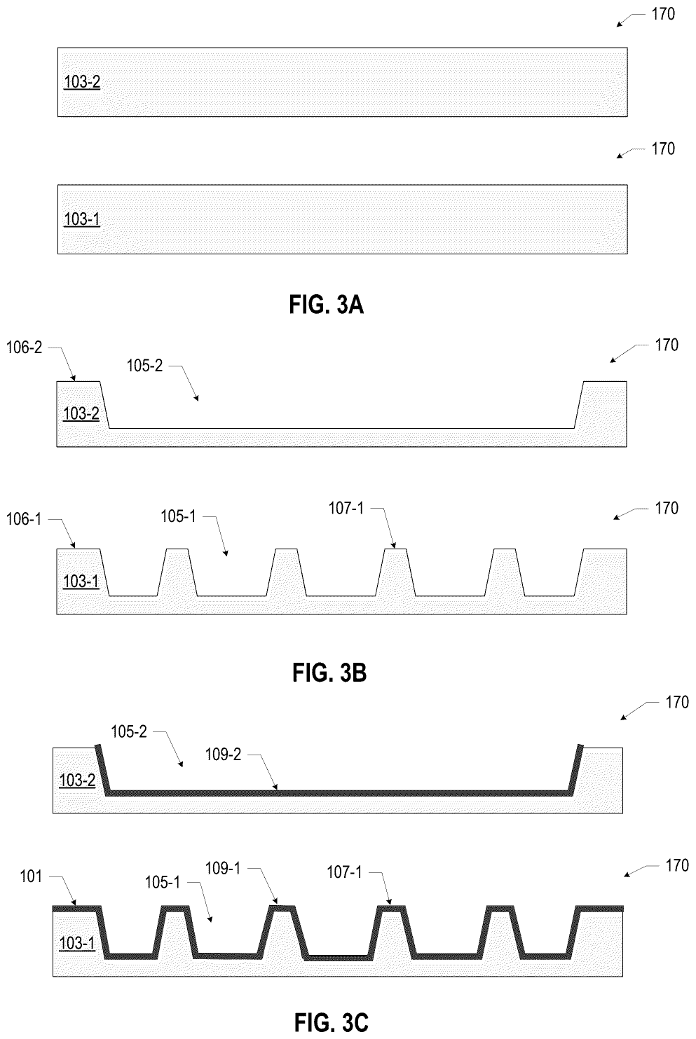

Any suitable techniques may be used to manufacture the cores with a cavity filter structure disclosed herein. For example, FIGS. 3A-3F are side, cross-sectional views of various stages in an example process for manufacturing the core 103 of FIG. 1B, in accordance with various embodiments. Although the operations discussed below with reference to FIGS. 3A-3F (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 3A-3F may be modified in accordance with the present disclosure to fabricate others of the cores 103 disclosed herein.

FIG. 3A illustrates a first core portion 103-1 and a second core portion 103-2 having a surface 170. The first and second core portions 103-1, 103-2 may be made of glass.

FIG. 3B illustrates a first core portion 103-1 subsequent to forming first trenches 105-1 and first ridges 107-1 in the surface 170 and a second core portion 103-2 subsequent to forming a second trench 105-2 in the surface 170. The first and second trenches 105-1, 105-2 and first ridges 107-1 may be formed using a laser-assisted etching process. The first core portion 103-1 may include a first bonding interface 106-1 (e.g., a first sidewall along a perimeter) and the second core portion 103-2 may include a second bonding interface 106-2 (e.g., a second sidewall along a perimeter).

FIG. 3C illustrates a first core portion 103-1 subsequent to plating a conductive material 109-1 in the first trenches 105-1 and on the first ridges 107-1 and a second core portion 103-2 subsequent to plating a conductive material 109-2 in the second trench 105-2. The first core portion 103-1 may further include a conductive material deposited on the surface 170 to form a signal trace inlet and outlet 101. The conductive material (e.g., 101, 109) may include any suitable metal material, such as copper.

FIG. 3D illustrates a first core portion 103-1 subsequent to depositing a bonding material 108-1 on a surface 170 and a second core portion 103-2 subsequent to depositing a bonding material 108-2 on a surface 170. The bonding material 108 may include any suitable material, as described above with reference to FIG. 1.

FIG. 3E illustrates an inverted a second core portion 103-2 and aligning the first and second core portions 103-1, 103-2.

FIG. 3F illustrates a core 103 subsequent to bonding the first and the second core portions 103-1, 103-2 together at the bonding interface 106.

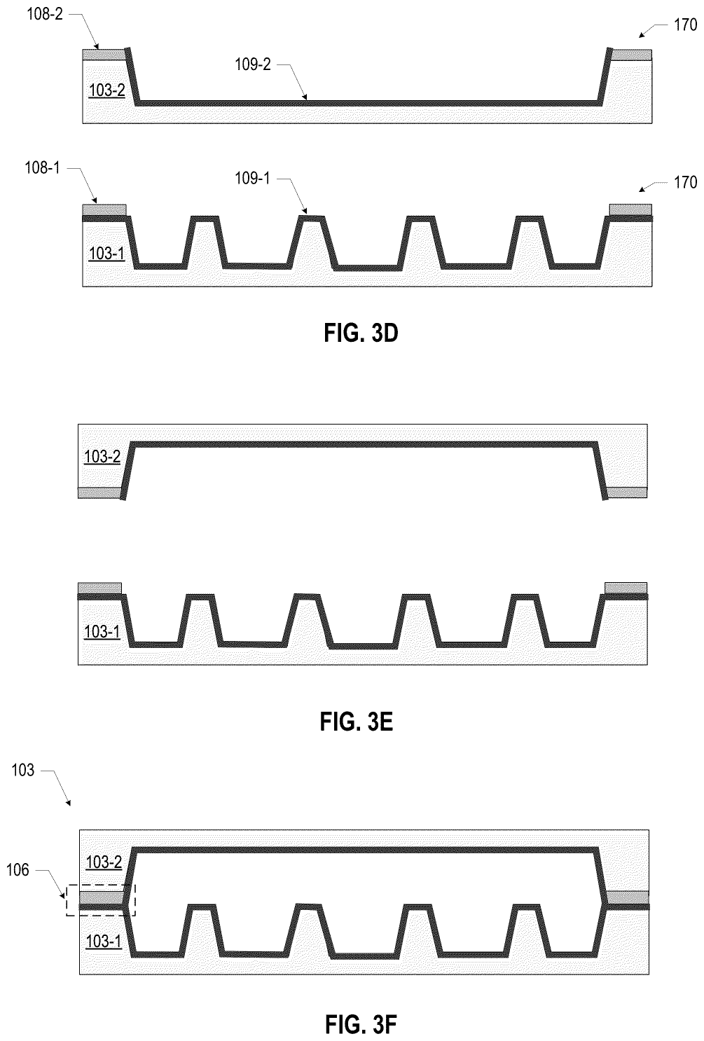

FIGS. 4A-4C are side, cross-sectional views of various stages in an example process for manufacturing an example core, in accordance with various embodiments. FIG. 4A illustrates first and second core portions 103-1, 103-2 according to the processes described above with reference to FIGS. 3A-3C including forming signal trace inlet and outlet 101 on both first and second core portions 103-1, 103-2.

FIG. 4B illustrates first and second core portions 103-1, 103-2 subsequent to depositing an insulting material 133 in the first trenches 105-1, around the first ridges 107-1, and in the second trench 105-2. The insulating material 133 may include any suitable material, as described above with reference to FIG. 2. The insulating may be initially deposited on and over the top surface of the first and second core portions 103-1, 103-2, then polished back. In such embodiments, the insulating material 133 may be removed using any suitable technique, including grinding, or etching, such as a wet etch, a dry etch (e.g., a plasma etch), a wet blast, or a laser ablation (e.g., using excimer laser). In some embodiments, the thickness of the insulating material 133 may be minimized to reduce the etching time required. In some embodiments, the top surface of the insulating material 133 may be planarized using any suitable process, such as chemical mechanical polishing (CMP).

FIG. 4C illustrates a core 103 subsequent to inverting the second core portion 103-2 and physically coupling the first and second core portions 103-1, 103-2 of FIG. 4B at the bonding interface 110. In some embodiments, the bonding interface 110 may be a hybrid bond interface, comprising metal-metal and dielectric-dielectric bonds. Insulating material 133-1, 133-2 in first and second core portions 103-1, 103-2 may bond with each other. The insulating material 133 may include organic materials or inorganic materials, for example, silicon and one or more of oxygen, nitrogen, and carbon (e.g., in the form of silicon oxide, silicon nitride, or silicon carbide), and/or other forms of inorganic dielectric material typically used as interlayer dielectric (ILD) in semiconductor devices, as described above with reference to FIG. 2. The bonded metal and dielectric materials form hybrid bonds, providing electrical and mechanical coupling between first and second core portions 103-1, 103-2.

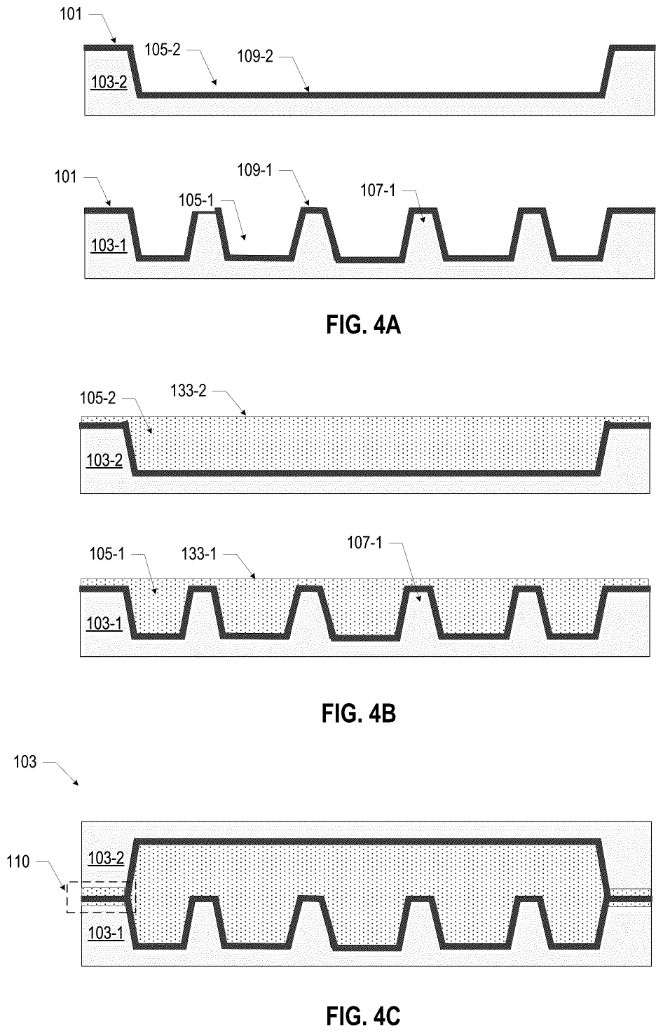

FIG. 5 illustrates an example microelectronic assembly 100 according to some embodiments of the present disclosure. A microelectronic assembly 100 may include a package substrate 128 having a core 103 with a cavity filter structure 102 integrated therein. The package substrate 128 may include a first RDL 148-1 on the first surface 171-1 of the core 103 and a second RDL 148-2 on a portion of the second surface 171-2 of the core 103. The first and second RDLs 148-1, 148-2 may include a dielectric material with conductive pathways 196 (e.g., including conductive traces and/or conductive vias, as shown) through the dielectric material. The first and second RDLs 148-1, 148-2 may be manufactured using any suitable technique, such as a PCB technique or a redistribution layer technique. In some embodiments, a dielectric material of the RDL 148 may include an oxide material, such as silicon and oxygen (e.g., in the form of silicon oxide), a nitride material, such as or silicon and nitrogen (e.g., in the form of silicon nitride), or an organic material. The core 103 may further include one or more through-glass vias (TGVs) (not shown) electrically coupling the first and second RDLs 148-1, 148-2. As used herein, the core 103 with the second RDL 148-2 and/or the first RDL 148-1 may be referred to as a package substrate 128.

The microelectronic assembly 100 may further include a die 114 electrically coupled to the package substrate 128 by interconnects 150 and a circuit board 131 electrically coupled to the package substrate 128 by interconnects 190. Interconnects 150 disclosed herein may take any suitable form, including solder balls for a ball grid array arrangement, pins in a pin grid array arrangement or lands in a land grid array arrangement. Interconnects 190 disclosed herein may take any suitable form, including any of the forms described above with reference to interconnects 150. The circuit board 131 may be a motherboard, for example, and may have other components attached to it. The circuit board may include conductive pathways and other conductive contacts for routing power, ground, and signals through the circuit board, as known in the art. In some embodiments, the interconnects 190 may not couple to a circuit board 131, but may instead couple to another IC package, an interposer, or any other suitable component.

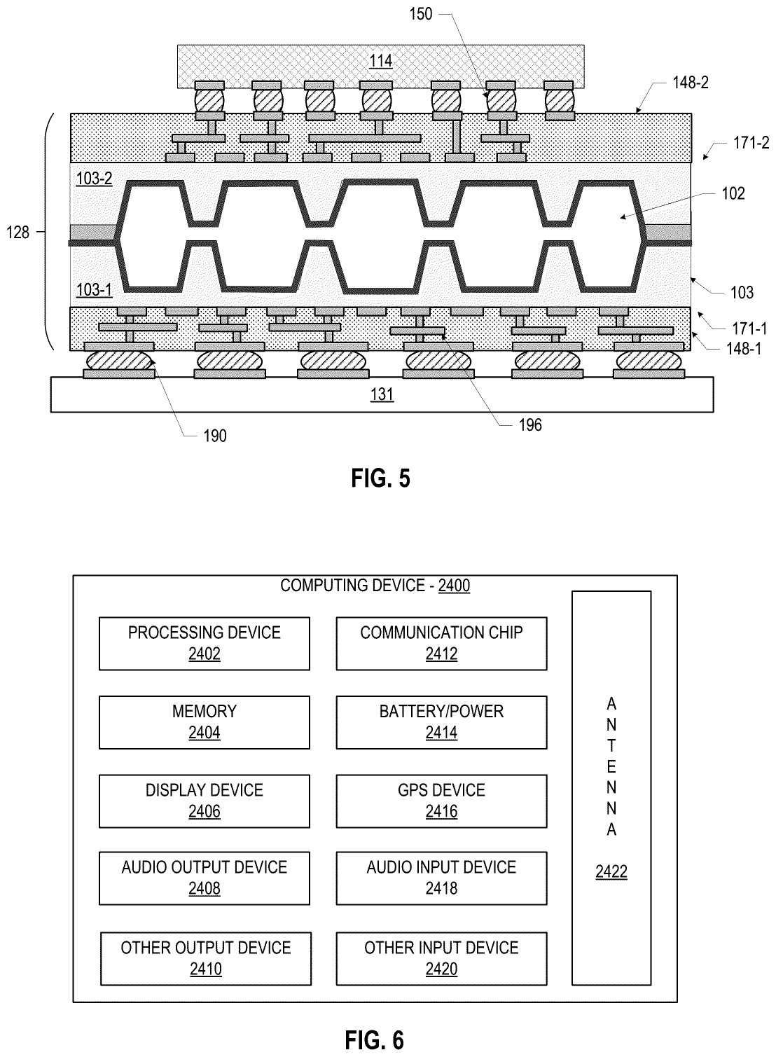

FIG. 6 is a block diagram of an example computing device 2400 that may include one or more components having one or more IC packages in accordance with any of the embodiments disclosed herein. A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single die that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SoC).

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more Digital Signal Processors (DSPs), Application Specific ICs (ASIC), Central Processing Units (CPUs), Graphics Processing Units (GPUs), cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

Example 1 is an integrated circuit (IC) package substrate, including a core made of glass, the core including a first core portion having a first surface and a trench and a ridge in the first surface, the trench and the ridge lined with a conductive material; and a second core portion having a second surface, the second surface lined with the conductive material, wherein the first surface of the first core portion is physically coupled to the second surface of the second core portion forming a cavity filter structure.

Example 2 may include the subject matter of Example 1, and may further specify that the first core portion is physically coupled to the second core portion by a die attach film (DAF), a non-conductive adhesive, a B-stage underfill, or a polymer film with adhesive property.

Example 3 may include the subject matter of Examples 1 or 2, and may further specify that the first core portion is physically coupled to the second core portion by glass-to-glass bonds.

Example 4 may include the subject matter of Examples 1 or 2, and may further specify that the first core portion is physically coupled to the second core portion by hybrid bonds.

Example 5 may include the subject matter of any of Examples 1-4, and may further include a signal trace inlet and a signal trace outlet conductively coupled to the conductive material lining the trench and the ridge in the first core portion, and to the conductive material lining the surface of the second core portion.

Example 6 may include the subject matter of any of Examples 1-5, and may further specify that the trench is a first trench and the ridge is a first ridge, and the IC package substrate and may further include a second trench in the second surface of the second core portion, the second trench lined with the conductive material.

Example 7 may include the subject matter of any of Examples 1-5, and may further specify that the trench is a plurality of first trenches and the ridge is a plurality of first ridges, and the IC package substrate and may further include a plurality of second trenches and a plurality of second ridges in the second surface of the second core portion, wherein the plurality of first trenches and first ridges are symmetrically aligned with the plurality of second trenches and second ridges.

Example 8 may include the subject matter of any of Examples 1-5, and may further specify that the trench is a plurality of first trenches and the ridge is a plurality of first ridges, and the IC package substrate and may further include a plurality of second trenches and a plurality of second ridges in the second surface of the second core portion, wherein the plurality of first trenches and first ridges are asymmetrically aligned with the plurality of second trenches and second ridges.

Example 9 may include the subject matter of any of Examples 1-8, and may further include an insulating material in the trench.

Example 10 may include the subject matter of Example 9, and may further specify that the insulating material includes a mold material, a dielectric material, a photoresist material, a sacrificial material, or a thermal decomposable material.

Example 11 is an integrated circuit (IC) interposer, including a first portion having a first surface and a trench and a ridge in the first surface, the trench and the ridge lined with a conductive material; and a second portion having a second surface, the second surface lined with the conductive material, wherein the first surface of the first portion is physically coupled to the second surface of the second portion forming a cavity filter structure.

Example 12 may include the subject matter of Example 11, and may further specify that the first portion and the second portion are made of glass.

Example 13 may include the subject matter of Examples 11 or 12, and may further specify that the first portion is physically coupled to the second portion by a die attach film (DAF), a non-conductive adhesive, a B-stage underfill, or a polymer film with adhesive property.

Example 14 may include the subject matter of any of Examples 11-13, and may further specify that the first portion is physically coupled to the second portion by glass-to-glass bonds.

Example 15 may include the subject matter of any of Examples 11-13, and may further specify that the first portion is physically coupled to the second portion by hybrid bonds.

Example 16 may include the subject matter of any of Examples 11-15, and may further include a signal trace inlet and a signal trace outlet conductively coupled to the conductive material lining the trench and the ridge in the first portion, and to the conductive material lining the surface of the second portion.

Example 17 may include the subject matter of any of Examples 11-16, and may further specify that the trench is a plurality of first trenches and the ridge is a plurality of first ridges, and the IC interposer and may further include a plurality of second trenches and a plurality of second ridges in the second surface of the second portion, wherein the plurality of first trenches and first ridges are symmetrically aligned with the plurality of second trenches and second ridges.

Example 18 may include the subject matter of any of Examples 11-16, and may further specify that the trench is a plurality of first trenches and the ridge is a plurality of first ridges, and the IC interposer and may further include a plurality of second trenches and a plurality of second ridges in the second surface of the second portion, wherein the plurality of first trenches and first ridges are asymmetrically aligned with the plurality of second trenches and second ridges.

Example 19 may include the subject matter of any of Examples 11-18, and may further include an insulating material in the trench.

Example 20 may include the subject matter of Example 19, and may further specify that the insulating material includes a mold material, a dielectric material, a photoresist material, a sacrificial material, or a thermal decomposable material.

Example 21 is a microelectronic assembly, including a package substrate, including a core made of glass, the core including a first core portion having a first surface and a first trench and a first ridge in the first surface, the first trench and the first ridge lined with a conductive material; and a second core portion having a second surface and a second trench and a second ridge in the second surface, the second trench and the second ridge lined with the conductive material, wherein the first surface of the first core portion with the first trench and first ridge is physically coupled to the second surface of the second core portion with the second trench and the second ridge forming a cavity filter structure; and a die electrically coupled to the package substrate.

Example 22 may include the subject matter of Example 21, and may further specify that the first core portion is physically coupled to the second core portion by a die attach film (DAF), a non-conductive adhesive, a B-stage underfill, or a polymer film with adhesive property.

Example 23 may include the subject matter of Examples 21 or 22, and may further specify that the first core portion is physically coupled to the second core portion by glass-to-glass bonds.

Example 24 may include the subject matter of Examples 21 or 22, and may further specify that the first core portion is physically coupled to the second core portion by hybrid bonds.

Example 25 may include the subject matter of any of Examples 21-24, and may further include a signal trace inlet and a signal trace outlet conductively coupled to the conductive material lining the first trench and the first ridge in the first core portion, and to the conductive material lining the second trench and the second ridge in the second core portion.

Example 26 may include the subject matter of any of Examples 21-25, and may further specify that the first trench and the first ridge are symmetrically aligned with the second trench and second ridge.

Example 27 may include the subject matter of any of Examples 21-25, and may further specify that the first trench and the first ridge are asymmetrically aligned with the second trench and second ridge.

Example 28 may include the subject matter of any of Examples 21-27, and may further include an insulating material in the first and second trenches.

Example 29 may include the subject matter of Example 28, and may further specify that the insulating material includes a mold material, a dielectric material, a photoresist material, a sacrificial material, or a thermal decomposable material.

1. An integrated circuit (IC) package substrate, comprising:
a core made of glass, the core including:
a first core portion having a first surface and a trench and a ridge in the first surface, the trench and the ridge lined with a conductive material; and
a second core portion having a second surface, the second surface lined with the conductive material, wherein the first surface of the first core portion is physically coupled to the second surface of the second core portion forming a cavity filter structure.

2. The IC package substrate of claim 1, wherein the first core portion is physically coupled to the second core portion by a die attach film (DAF), a non-conductive adhesive, a B-stage underfill, or a polymer film with adhesive property.

3. The IC package substrate of claim 1, wherein the first core portion is physically coupled to the second core portion by glass-to-glass bonds.

4. The IC package substrate of claim 1, wherein the first core portion is physically coupled to the second core portion by hybrid bonds.

5. The IC package substrate of claim 1, further comprising:
a signal trace inlet and a signal trace outlet conductively coupled to the conductive material lining the trench and the ridge in the first core portion, and to the conductive material lining the surface of the second core portion.

6. The IC package substrate of claim 1, wherein the trench is a first trench and the ridge is a first ridge, and the IC package substrate further comprising:
a second trench in the second surface of the second core portion, the second trench lined with the conductive material.

7. The IC package substrate of claim 1, wherein the trench is a plurality of first trenches and the ridge is a plurality of first ridges, and the IC package substrate further comprising:
a plurality of second trenches and a plurality of second ridges in the second surface of the second core portion, wherein the plurality of first trenches and first ridges are symmetrically aligned with the plurality of second trenches and second ridges.

8. The IC package substrate of claim 1, wherein the trench is a plurality of first trenches and the ridge is a plurality of first ridges, and the IC package substrate further comprising:
a plurality of second trenches and a plurality of second ridges in the second surface of the second core portion, wherein the plurality of first trenches and first ridges are asymmetrically aligned with the plurality of second trenches and second ridges.

9. The IC package substrate of claim 1, further comprising:
an insulating material in the trench.

10. The IC package substrate of claim 9, wherein the insulating material includes a mold material, a dielectric material, a photoresist material, a sacrificial material, or a thermal decomposable material.

11. An integrated circuit (IC) interposer, comprising:
a first portion having a first surface and a trench and a ridge in the first surface, the trench and the ridge lined with a conductive material; and
a second portion having a second surface, the second surface lined with the conductive material, wherein the first surface of the first portion is physically coupled to the second surface of the second portion forming a cavity filter structure.

12. The IC interposer of claim 11, wherein the first portion and the second portion are made of glass.

13. The IC interposer of claim 11, further comprising:
a signal trace inlet and a signal trace outlet conductively coupled to the conductive material lining the trench and the ridge in the first portion, and to the conductive material lining the surface of the second portion.

14. The IC interposer of claim 11, wherein the trench is a plurality of first trenches and the ridge is a plurality of first ridges, and the IC interposer further comprising:
a plurality of second trenches and a plurality of second ridges in the second surface of the second portion, wherein the plurality of first trenches and first ridges are symmetrically aligned with the plurality of second trenches and second ridges.

15. The IC interposer of claim 11, wherein the trench is a plurality of first trenches and the ridge is a plurality of first ridges, and the IC interposer further comprising:
a plurality of second trenches and a plurality of second ridges in the second surface of the second portion, wherein the plurality of first trenches and first ridges are asymmetrically aligned with the plurality of second trenches and second ridges.

16. A microelectronic assembly, comprising:
a package substrate, including:
a core made of glass, the core including:
a first core portion having a first surface and a first trench and a first ridge in the first surface, the first trench and the first ridge lined with a conductive material; and
a second core portion having a second surface and a second trench and a second ridge in the second surface, the second trench and the second ridge lined with the conductive material, wherein the first surface of the first core portion with the first trench and first ridge is physically coupled to the second surface of the second core portion with the second trench and the second ridge forming a cavity filter structure; and
a die electrically coupled to the package substrate.

17. The microelectronic assembly of claim 16, further comprising:
a signal trace inlet and a signal trace outlet conductively coupled to the conductive material lining the first trench and the first ridge in the first core portion, and to the conductive material lining the second trench and the second ridge in the second core portion.

18. The microelectronic assembly of claim 16, wherein the first trench and the first ridge are symmetrically aligned with the second trench and second ridge.

19. The microelectronic assembly of claim 16, wherein the first trench and the first ridge are asymmetrically aligned with the second trench and second ridge.

20. The microelectronic assembly of claim 16, further comprising:
an insulating material in the first and second trenches.
